(19) United States
(12) Patent Application Publication
(10) Pub. No.: US 2003/0100174 A1
(43) Pub. Date: May 29, 2003

(54) Process for making a ball grid array semiconductor package

(75) Inventors: Jansen Chiu, Kaohsiung (TW); Taurus Chao, Pingtung (TW)

Correspondence Address: DOUGHERTY & TROXELL, SUITE 1404, 5205 LEESBURG PIKE, FALLS CHURCH, VA, 22041, US

(73) Assignee: Walsin Advanced Electronics LTD

(21) Appl. No.: 09/994,708

(22) Filed: Nov. 28, 2001

(51) Int. Cl. H01L 21/44

(52) U.S. Cl. 438/612

(57) ABSTRACT

A process for making a ball grid array semiconductor package comprises the steps of: providing a substrate, dispensing adhesive, attaching dice(s) on the substrate, wire bonding, and implanting solder balls. The adhesive with a predetermined viscosity is coated on the adhesive area of the substrate by dispensing or potting to form a specific pattern for die-attaching. The adhesive is easily controlled to avoid covering the bonding pads on the active surface of the die, so that the yield of the semiconductor package is improved without increasing the extra cost. Also, the reliability of the semiconductor package is increased and the manufacturing cost is reduced.

### FIELD OF THE INVENTION

The present invention is relating to semiconductor package, particularly to a process for making a ball grid array (BGA) semiconductor package by potting or dispensing adhesive on a BGA substrate with a window for die-attaching.

### BACKGROUND OF THE INVENTION

A window ball grid array semiconductor package and a packaging method are disclosed in U.S. Pat. No. 6,190,943 entitled “Chip scale packaging method”. As shown in FIG. 1, a semiconductor package 20 with window ball grid array configuration comprises a substrate 22 with a window, a die 24, a package body 42, a thermoplastic adhesive 28, a plurality of metal bonding wires 32, and a plurality of solder balls 44. The substrate 22 has a slender window 34 passing through its upper surface 30 and lower surface 38. The active surface 26 of the die 24 is adhered on the upper surface 30 of substrate 22 by thermoplastic adhesive 28. The metal bonding wires 32 electrically connect die 24 and substrate 22 passing through the window 34. The package body 42 is formed at the perimeter of die 24 and window 34 for protecting die 24 and metal bonding wires 32. The solder balls 44 arranged in grid array fashion are formed on the lower surface 38 of the substrate 22. Therefore, the semiconductor package 20 has a type of window ball grid array.

The packaging method of the semiconductor package 20 also is described as follows. The first step is to provide a substrate 22. The substrate 22 has an upper surface 30, a lower surface 38, and a window 34 passing through the upper surface 30 and the lower surface 38. The second step is to coat a liquid thermoplastic adhesive 28 on the partial upper surface 30 of the substrate 22 by stenciling method. The third step is to let the active surface 26 of the die 24 contact the thermoplastic adhesive 28 on the substrate 22 for making bonding pads 36 of active surface 26 of the die 24 correspond to the window 34. The fourth step is to press and heat substrate 22 and die 24 under the conditions of pre-set temperature (190° C.), pressure (390 g), and time (5 seconds) for attaching the die 24 on the substrate 22. The fifth step is that the metal bonding wires 32 pass through the window 34 to electrically connect bonding pads 36 of the die 24 and conductive pads 41 of the substrate 22. The sixth step is to form a package body 42 at the perimeter of die 24 and window 34. The seventh step is to implant a plurality of solder balls 44 which arrange in grid array fashion on the lower surface 38 of the substrate 22.

Semiconductor package 20 (that is window ball grid array package) is manufactured by means of the steps mentioned above. The thermoplastic adhesive 28 is coated by stenciling method and is formed on the partial upper surface 30 of substrate 22 ( in the second step), so that it is uneasy to control the flow of liquid thermoplastic adhesive 28 during thermal pressing die 24 and substrate 22, resulting in overflow of the liquid thermoplastic adhesive 28 and covering the bonding pads 36 of die 24 . Then a fail of wire-bonding happens. Accordingly, it must be precisely controlled about the quantity of coating the thermoplastic adhesive 28 by stenciling method in order to reach a good product yield and enhance the reliability of semiconductor package. Besides, for the semiconductor packaging industry, the thermoplastic adhesive 28 (like one kind of non-solvent, elastic, and semi-transparent silicon rubber) is not produced and used widely yet, so that the cost is still high. Furthermore, in the familiar semiconductor packaging process, the die-attaching method is to pressure and heat simultaneously (the step four). However, the machine unit that performs pressuring and heating operations simultaneously is complicated and expensive to cause high packaging manufacturing cost.

### SUMMARY

The main object of the present invention is to provide a process for making a ball grid array semiconductor package. An adhesive is coated on the adhesive areas of substrate by dispensing or potting, then a die is pressured to attach on the substrate and heating until the adhesive is solidified, so the die is closely adhered on the substrate. The dies is also tightly adhered on the substrate even under molding process with higher temperature to form a package body. Besides, the quantity of the adhesive is easy to control by dispensing or potting, so that the yield of the semiconductor package is enhanced without increasing the material cost.

The secondary object of the present invention is to provide a process for making a ball grid array semiconductor package. In order to manufacture the semiconductor package, the adhesive mentioned above is one kind of thermosetting or thermoplastic adhesive, such as epoxy adhesive or Ag-epoxy adhesive, etc. The adhesive is produced and used widely so that there is a low cost. Furthermore, the process for making a ball grid array semiconductor package comprises the step of executing pressuring operation prior to and the step of heating by individual apparatuses without using the expensive machine unit with pressing and heating functions simultaneously, so that the manufacturing cost can be reduced.

In the process according to the present invention, the adhesive is dispensed or potted on the adhesive areas of the substrate. Then, the active surface of die is adhered on the adhesive areas of the substrate and heated to solidify the adhesive, so that the die is tightly adhered on the substrate. Next, wire bonding and encapsulating operations are executed. The encapsulating method is molding, printing or potting, etc. A package body with good sealing is formed after encapsulating and curing. The die is still tightly adhered on the substrate during the step of forming the package body with high temperature. So that the process for making a ball grid array semiconductor package enhances reliability of the semiconductor package and reduces manufacturing cost.

### DESCRIPTION OF THE DRAWINGS

FIG. 1 is a cross-sectional view of a window BGA package disclosed in U.S. Pat. No. 6,190,943 entitled “chip scale packaging method”.

FIG. 2a is a cross-sectional view illustrating a provided substrate in a process for making a ball grid array semiconductor package in accordance with an embodiment of the present invention.

FIG. 2b is a cross-sectional view illustrating the substrate with potted adhesive in the process for making a ball grid array semiconductor package in accordance with the embodiment of the present invention.

FIG. 2c is a cross-sectional view illustrating the substrate adhering with dies in the process for making a ball grid array semiconductor package in accordance with an embodiment of the present invention.

FIG. 2d is a cross-sectional view illustrating the substrate after wire-bonding and encapsulating in the process for making a ball grid array semiconductor package in accordance with an embodiment of the present invention.

FIG. 2e is a cross-sectional view illustrating the substrate after implanting solder balls in the process for making a ball grid array semiconductor package in accordance with an embodiment of the present invention.

FIG. 3 is a top view illustrating the substrate with dispensing adhesive in the process for making a ball grid array semiconductor package in accordance with another embodiment of the present invention.

FIG. 4 is a cross-sectional view of a ball grid array package made by the process in accordance with an embodiment of the present invention.

### DETAILED DESCRIPTION OF THE PRESENT INVENTION

Referring to the drawings attached, the present invention will be described by means of the embodiments below.

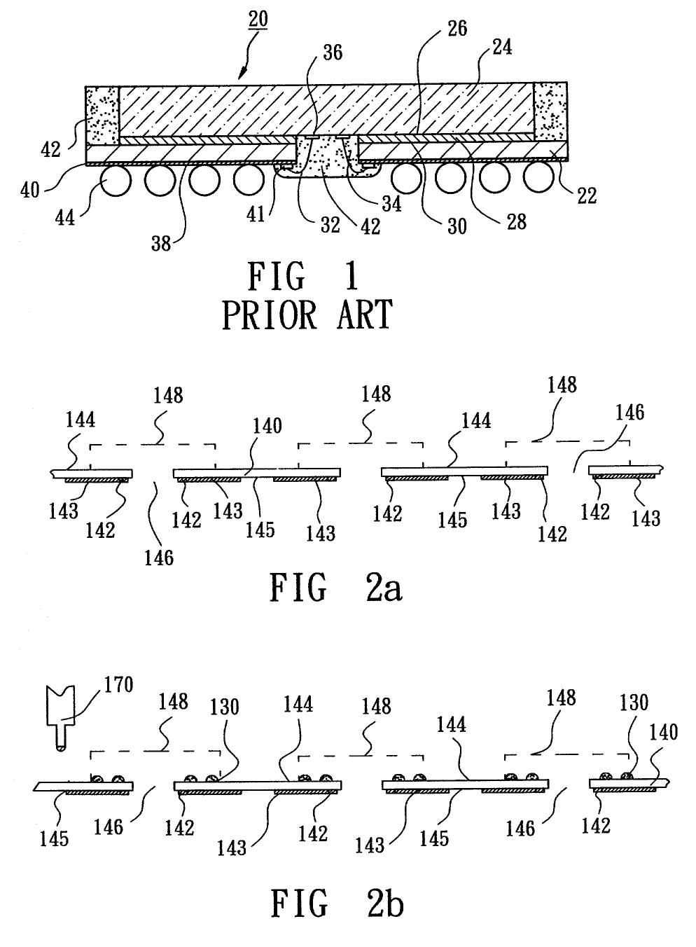

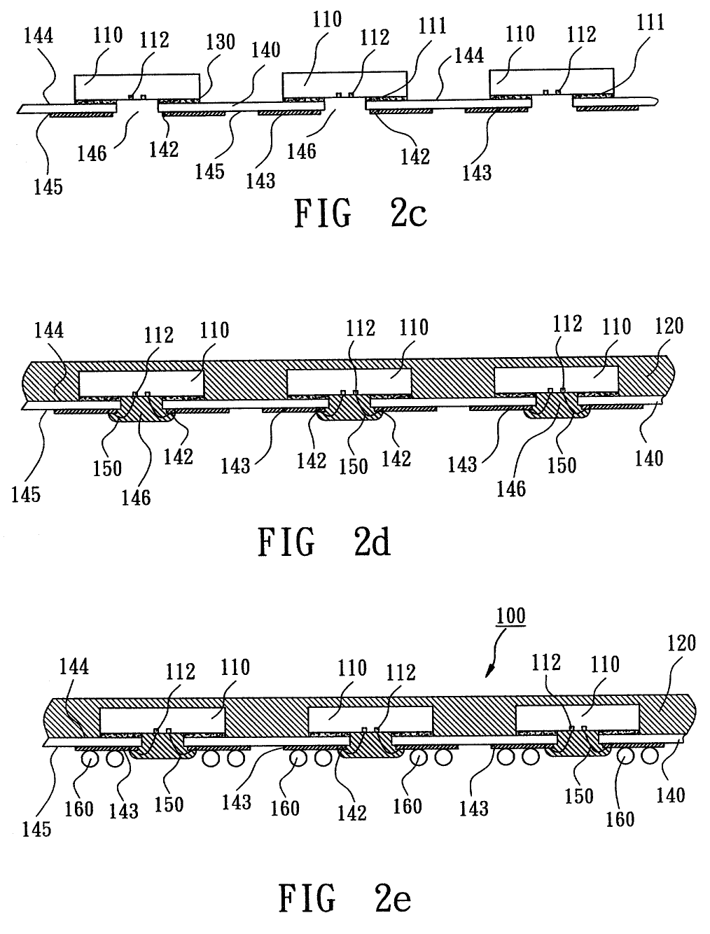

According to an embodiment of the present invention, from FIG. 2a to FIG. 2e are cross-sectional views of a substrate in the steps of the process. FIG. 4 is a cross-sectional view of a BGA package made by the process.

As shown in FIG. 4, the BGA package 100 comprises a die 110, a package body 120, an adhesive 130, a substrate 140, a plurality of metal bonding wires 150, and a plurality of bonding balls 160. The substrate 140 has a window 146 passing through the upper surface 144 the lower surface 145 of substrate 140. The active surface 111 of the die 110 is adhered on the upper surface 144 of the substrate 140 by the adhesive 130. The metal bonding wires 150 pass through the window 146 and electrically connect die 110 and substrate 140 by means of wire bonding method. The package body 120 is used to seal die 110 and metal bonding wires 150 for protecting the die 110 and metal bonding wires 150 from the injury of hostile environment. The solder balls 160, such as lead-tin alloy, arranged in grid array fashion are formed on the lower surface 145 of the substrate 140, therefore a BGA package is constituted.

According to the present invention, a process for making the BGA package mentioned above will be described as following.

As shown in FIG. 2a, at first a substrate 140 is provided, which has an upper surface 144 and a lower surface. There is at least a die-attaching area 148 on the upper surface 144 of the substrate 140. There is at least a window 146 passing through the upper surface 144 and the lower surface 145 of substrate 140 at the die-attaching area 148. A conductive layer 143 is formed on the lower surface 145 of substrate 140, and the conductive layer 143 includes a plurality of metal traces (not shown in the drawing) and contact pads 142 near the perimeters of the window 146. The metal traces are used for electrically connecting with solder balls 160 (as shown in FIG. 2e), and the contact pads 142 are used for bonding the metal bonding wires 150 (as shown in FIG. 2d).

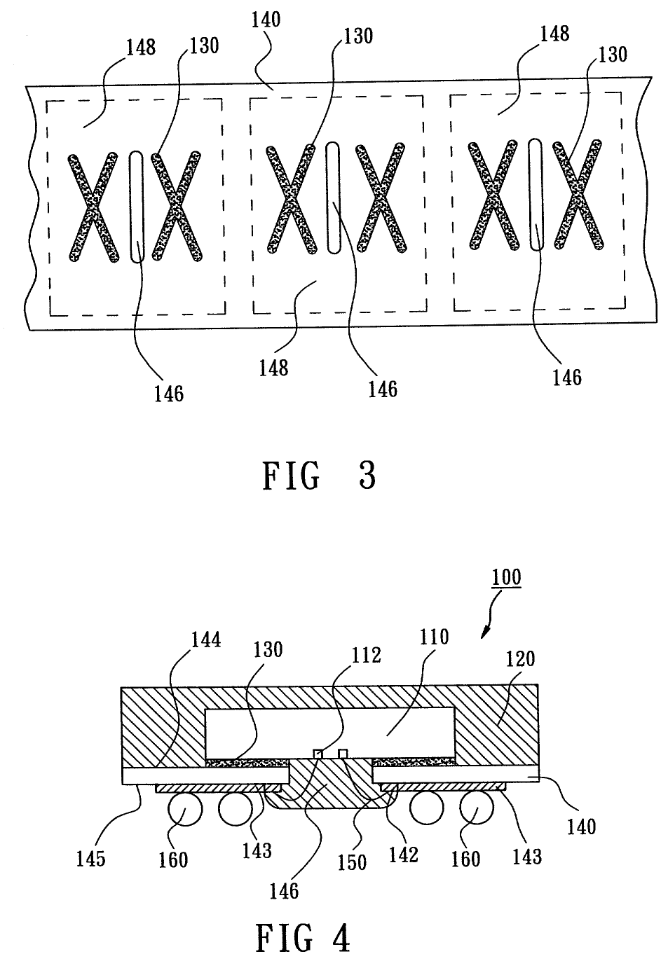

As shown in FIG. 2b, the adhesive 130 is potted on the die-attaching areas 148 of upper surface 144 of the substrate 140 with specific pattern by means of a dispenser 170. Alternatively, the adhesive 130 is coated on the adhesive areas 148 of substrate 140 by dispensing method according to another embodiment (as shown in FIG. 3). The adhesive 130 is thermosetting epoxy adhesive or Ag-epoxy adhesive, or thermoplastic adhesive with a predetermined viscosity for preventing from covering the bonding pads 112 of dies 110.

Next, as shown in FIG. 2c, the active surfaces 111 of a plurality of dies 110 are put to contact the adhesive 130 on the die-attaching areas 148 of the substrate 140, and the dies 110 are pressed to adhere to the substrate 140 with a proper pressure. The bonding pads 112 of each die 110 are located at the corresponding center area of active surface 111 of die 110 exposed from the window 146 after die-attaching. If the adhesive 130 is a thermosetting compound, the substrate 140 is heated by pre-set temperature (about 150° C. to 175° C.) for curing the adhesive 130, so that the dies 110 are tightly adhered on the substrate 140.

Then, as shown in FIG. 2d, the metal bonding wires 150 electrically connect the bonding pads 112 of the dies 110 and the contact pads 142 of the conductive layer 143 of the substrate 140 passing through the window 146 of the substrate 140 by wire bonding method. Thereafter, a package body 120 is formed by molding, printing, or potting method to seal the dies 110 and the metal bonding wires 150, and is heated by high temperature (about 150° to 180° C.) to closely combine die 110 and substrate 140.

Finally, as shown in FIG. 2e, the soldering balls 160 are implanted on the conductive layer 143 of lower surface 145 of the substrate 140 and are arranged in grid array fashion. Accordingly, the BGA packages 100 with window are formed on the substrate 140. Thereafter, the substrate 140 is diced to singulate the BGA packages 100 (as shown in FIG. 4).

In the process 100 for making a BGA package 100, the adhesive 130 is coated on the adhesive areas 148 of upper surface 144 of substrate 140 with a specific pattern by a dispenser 170, such as dispensing or potting. The quantity of the adhesive is well controlled, the manufacturing cost is low, and the yield of the semiconductor package is improved without increasing extra cost. Before heating to curing the adhesive 130, the dies 110 are pressed to attach on the substrate 140 without the adhersive 130 covering the bonding pads 112 of dies 110. Then, the heating process is executed, wherein the curing temperature of the adhesive 130 is 150° C. to 175° C. approximately. After curing, the adhesive 130 make the dies 110 closely adhere on the substrate 140 for easily executing the following wire bonding and encapsulating steps. The encapsulating step is to provide a thermosetting epoxy by molding, printing, or potting method. The curing temperature of thermosetting epoxy is about 150° C. to 180° C., and a package body 120 is formed to combine the die(s) 110 and the substrate 140 tightly. Moreover, in the semiconductor packaging industry, the adhesive 130 (such as epoxy adhesive or Ag-epoxy adhesive, etc) had been produced and used widely, so that the adhesive 130 can be used widely at low cost during the semiconductor packaging process. Since the packaging process of the BGA package 100 is pressing prior to heating, the familiar dispenser and cheap oven are requested to install without further buying and using expensive machine with pressing and heating functions simultaneously. Therefore, it decreases the manufacturing cost about adhesive 130 and manufacturing equipments.

The above description of embodiments of this invention is intended to be illustrative and not limiting. Other embodiments of this invention will be obvious to those skilled in the art in view of the above disclosure.

What is claimed is:

1. A process for making a semiconductor package comprising the steps of:
providing a substrate having an upper surface and a lower surface, wherein the substrate has at least a die-attaching area on the upper surface, a conductive layer formed on the lower surface, and at least a window passing through the substrate;
coating an adhesive with a predetermined viscosity on the die-attaching area of the substrate to form a specific pattern by means of dispensing or potting;
pressing a die onto the die-attaching area of the substrate, wherein the active surface of the die has bonding pads exposed from the window;
electrically connecting the bonding pads of the die with the substrate via the window; forming a thermosetting package body; and
implanting the soldering balls on the conductive layer of the lower surface of the substrate.

2. The process in accordance with claim 1, wherein the adhesive is a thermosetting compound.

3. The process in accordance with claim 1, further comprising the step of curing the thermosetting adhesive after the step of pressing.

4. The process in accordance with claim 1, wherein the curing temperature is between 150° C. and 175° C.

5. The process in accordance with claim 1, wherein the adhesive is a thermoplastic compound.

6. The process in accordance with claim 1, wherein the conductive layer on the lower surface of the substrate includes at least a contact pad for connecting a bonding wire.

7. The process in accordance with claim 1, wherein the solder balls are implanted in the arrangement of grid array fashion to form a ball grid array semiconductor package.
